(19) United States
(12) Patent Application Publication
(10) Pub. No.: US 2025/0377422 A1
(43) Pub. Date: Dec. 11, 2025

(54) MAGNETIC SENSOR

(71) Applicant: TDK CORPORATION, Tokyo (JP)

(72) Inventors: Hidekazu KOJIMA, Tokyo (JP); Hirokazu TAKAHASHI, Tokyo (JP); Takashi SAITO, Tokyo (JP); Satoshi MIURA, Tokyo (JP)

(73) Assignee: TDK CORPORATION, Tokyo (JP)

(21) Appl. No.: 19/204,790

(22) Filed: May 12, 2025

(30) Foreign Application Priority Data
Jun. 6, 2024 (JP) 2024-092225

(51) Int. Cl. G01R 33/09

(52) U.S. Cl. CPC G01R 33/093

(57) ABSTRACT

A magnetic sensor includes an MR element disposed on an inclined surface, and a magnetic field generator disposed on the inclined surface and configured to generate a magnetic field to be applied to the MR element. The magnetic field generator includes a bottom surface, a top surface, and a side surface. The side surface of the magnetic field generator includes a first part located at an end in a first direction and a second part located at an end in a second direction. A second angle that the second part forms with the top surface is greater than a first angle that the first part forms with the top surface.

### CROSS REFERENCE TO RELATED APPLICATIONS

This application claims the benefit of Japanese Priority Patent Application No. 2024-092225 filed on Jun. 6, 2024, the entire contents of which are incorporated herein by reference.

### BACKGROUND

The disclosure relates to a magnetic sensor configured to be capable of applying a bias magnetic field to a magnetoresistive element.

Magnetic sensors have been used for various applications in recent years. Examples of known magnetic sensors include one that uses a spin-valve magnetoresistive element provided on a substrate. The spin-valve magnetoresistive element includes a magnetization pinned layer whose magnetization direction is fixed, a free layer whose magnetization direction is variable depending on the direction of a magnetic field applied thereto, and a gap layer disposed between the magnetization pinned layer and the free layer. Spin-valve magnetoresistive elements provided on a substrate are often configured to be sensitive to magnetic fields in a direction parallel to the surface of the substrate. Thus, such magnetoresistive elements are suitable for detecting magnetic fields that vary in direction in a plane parallel to the surface of the substrate.

On the other hand, some systems including a magnetic sensor are intended to detect a magnetic field including a component in a direction perpendicular to the surface of the substrate by using magnetoresistive elements provided on the substrate. In such a case, the magnetic field including the component in the direction perpendicular to the surface of the substrate can be detected by disposing the magnetoresistive elements on an inclined surface formed on the substrate.

Incidentally, some magnetic sensors include a means for applying a bias magnetic field to the magnetoresistive element. The bias magnetic field is used, for example, to cause the magnetoresistive element to respond linearly to a change in the strength of the target magnetic field, which is the magnetic field to be detected. In a magnetic sensor that uses a spin-valve magnetoresistive element, the bias magnetic field is used also to make the free layer have a single magnetic domain and to orient the magnetization direction of the free layer in a certain direction, when there is no target magnetic field.

Japanese Patent Application Publication No. 2006-261401 discloses a magnetic sensor in which a Z-axis sensor is provided on slopes of a plurality of projection portions on a substrate. Magnetoresistive elements constituting the Z-axis sensor include a magnetosensitive element provided along the longitudinal direction of the slope, and a bias magnet portion that applies a bias magnetic field to the magnetosensitive element.

Japanese Patent Application Publication No. 2016-176911 discloses a magnetic sensor including a magnetoresistive element and two magnetic field generators disposed with the magnetoresistive element interposed therebetween. The magnetic field generators include an antiferromagnetic layer and a ferromagnetic layer stacked together, and are configured to apply a bias magnetic field to the magnetoresistive element.

In magnetic field generators such as that disclosed in Japanese Patent Application Publication No. 2016-176911, the strength of the bias magnetic field generated by the magnetic field generator can be increased by increasing the volume of the magnetic field generator. However, when an attempt is made to form a magnetic field generator on an inclined surface as in the magnetic sensor as disclosed in Japanese Patent Application Publication No. 2006-261401, the volume of the magnetic field generator may be smaller than when the magnetic field generator is formed on a plane.

### SUMMARY

A magnetic sensor according to one embodiment of the disclosure includes a support member including an inclined surface inclined relative to a reference plane, a magnetoresistive element disposed on the inclined surface, and a magnetic field generator that is disposed on the inclined surface and is configured to generate a magnetic field to be applied to the magnetoresistive element. The magnetic field generator includes a bottom surface facing the inclined surface, a top surface opposite the bottom surface, and a side surface connecting the bottom surface and the top surface. The side surface includes a first part located at an end in a first direction, the first direction being along the inclined surface and away from the reference plane, and a second part located at an end in a second direction, the second direction being parallel to the reference plane and along the inclined surface. When a first angle is an angle that the first part forms with the top surface in a first cross section perpendicular to the second direction, and a second angle is an angle that the second part forms with the top surface in a second cross section perpendicular to each of the reference plane and the first cross section, the second angle is greater than the first angle.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a side view showing the magnetic sensor device shown in FIG. 1.

FIG. 3 is a functional block diagram showing a configuration of the magnetic sensor device shown in FIG. 1.

FIG. 4 is a circuit diagram showing a circuit configuration of a first detection circuit of the first example embodiment of the disclosure.

FIG. 5 is a circuit diagram showing a circuit configuration of a second detection circuit of the first example embodiment of the disclosure.

FIG. 6 is a plan view showing a part of the magnetic sensor according to the first example embodiment of the disclosure.

FIG. 7 is a cross-sectional view showing a part of a cross section at a position indicated by the 7-7 line in FIG. 6.

FIG. 8 is a cross-sectional view showing a part of a cross section at a position indicated by the 8-8 line in FIG. 6.

FIG. 9 is a plan view showing magnetoresistive elements, magnetic field generators, lower electrodes, and upper electrodes of the first example embodiment of the disclosure.

FIG. 10 is a perspective view showing the magnetoresistive element of the first example embodiment of the disclosure.

FIG. 11 is a side view showing the magnetic field generator of the first example embodiment of the disclosure.

FIG. 12 is a cross-sectional view showing a part of the magnetic sensor of the first example embodiment of the disclosure.

FIG. 13 is a cross-sectional view showing a part of the magnetic sensor of the first example embodiment of the disclosure.

FIG. 14 is an explanatory diagram for describing a shape of a side surface of the magnetic field generator of the first example embodiment of the disclosure.

FIG. 15 is an explanatory diagram for describing a shape of a side surface of the magnetic field generator of the first example embodiment of the disclosure.

FIG. 16 is a cross-sectional view showing one process in a manufacturing method of the magnetic sensor according to the first example embodiment of the disclosure.

FIG. 17 is a cross-sectional view showing a process following the process shown in FIG. 16.

FIG. 18 is a cross-sectional view showing a part of a first modification example of the magnetic sensor according to the first example embodiment of the disclosure.

FIG. 19 is a plan view showing magnetoresistive elements, magnetic field generators, lower electrodes, and upper electrodes of a second modification example of the magnetic sensor according to the first example embodiment of the disclosure.

FIG. 20 is a side view showing a magnetic field generator of a third modification example of the magnetic sensor according to the first example embodiment of the disclosure.

FIG. 21 is a side view showing a magnetic field generator of a fourth modification example of the magnetic sensor according to the first example embodiment of the disclosure.

FIG. 22 is a side view showing a magnetic field generator of a fifth modification example of the magnetic sensor according to the first example embodiment of the disclosure.

FIG. 23 is a side view showing a magnetic field generator of a sixth modification example of the magnetic sensor according to the first example embodiment of the disclosure.

FIG. 24 is a side view showing a magnetic field generator of a seventh modification example of the magnetic sensor according to the first example embodiment of the disclosure.

FIG. 25 is a cross-sectional view showing a part of a magnetic sensor of a second example embodiment of the disclosure.

### DETAILED DESCRIPTION

An object of the disclosure is to provide a magnetic sensor capable of increasing a strength of a magnetic field generated by a magnetic field generator disposed on an inclined surface.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

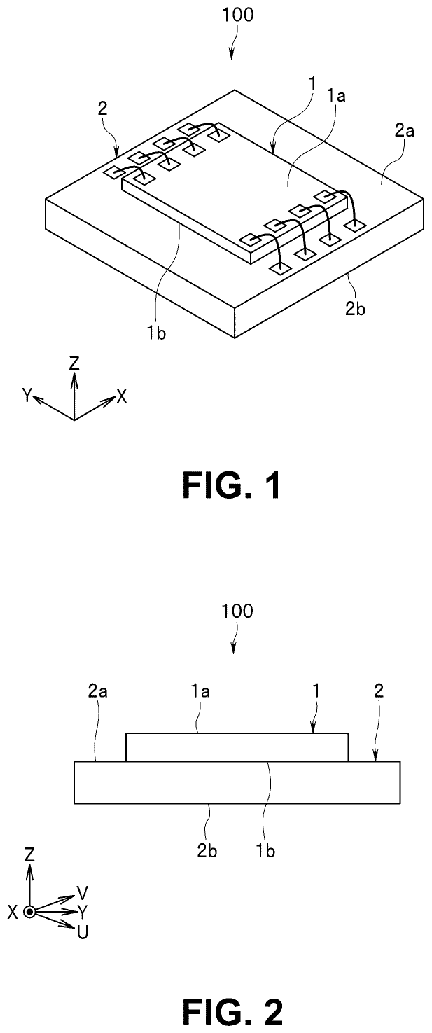

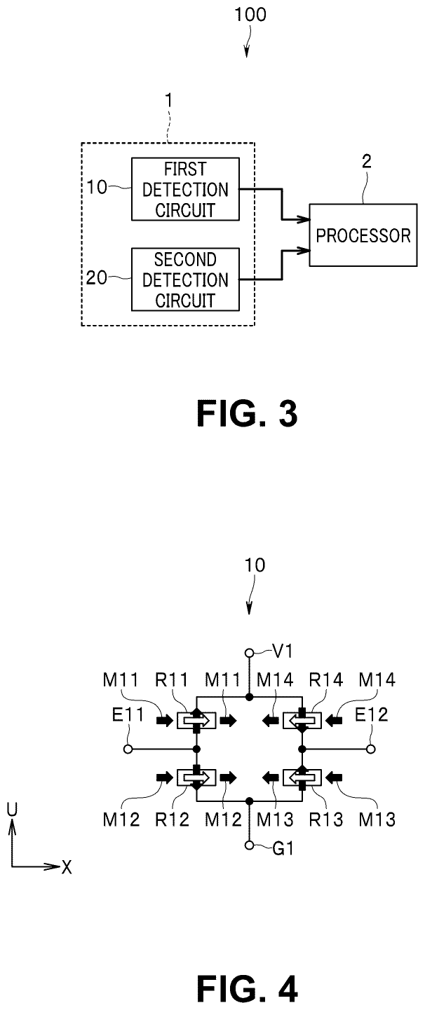

A configuration of a magnetic sensor device including a magnetic sensor according to a first example embodiment of the disclosure will initially be described with reference to FIGS. 1 through 3. FIG. 1 is a perspective view showing a magnetic sensor device 100. FIG. 2 is a side view showing the magnetic sensor device 100. FIG. 3 is a functional block diagram showing a configuration of the magnetic sensor device 100.

The magnetic sensor device 100 of the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic field sensor that detects the geomagnetic field, a magnetic sensor for a position detection device that detects the position of a magnet moving in a specific direction, a magnetic sensor for angle sensors or magnetic encoders that detects a rotating magnetic field, or a magnetic sensor for current sensors that detects a magnetic field generated by a current to be detected.

The processor 2 is configured to generate at least one detection value having a correspondence with the target magnetic field, based on the at least one detection signal. The processor 2 is constituted, for example, by an application-specific integrated circuit (ASIC).

The magnetic sensor 1 and the processor 2 are each in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other, and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by an adhesive, for example.

Now, X, Y, and Z directions are defined as shown in FIGS. 1 and 2. The X direction, the Y direction, and the Z direction are orthogonal to one another. In the example embodiment, the Z direction is a direction perpendicular to the top surface 1a of the magnetic sensor 1 and from the bottom surface 1b of the magnetic sensor 1 to the top surface 1a. The opposite directions to the X, Y, and Z directions will be expressed as —X, —Y, and —Z directions, respectively.

Hereinafter, the term “above” refers to positions located forward of a reference position in the Z direction, and “below” refers to positions opposite from the “above” positions with respect to the reference position. For each component of the magnetic sensor 1, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed from a position away in the specific direction or in one direction parallel to the specific direction.

As shown in FIG. 2, U and V directions are defined as follows. The U direction is a direction rotated from the Y direction to the −Z direction. The V direction is a direction rotated from the Y direction to the Z direction. In particular, in the example embodiment, the U direction is set to a direction rotated from the Y direction to the −Z direction by α, and the V direction is set to a direction rotated from the Y direction to the Z direction by α. Note that α is an angle greater than 0° and smaller than 90°. A −U direction refers to a direction opposite to the U direction, and a −V direction refers to a direction opposite to the V direction. The U direction and the V direction both are orthogonal to the X direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via the plurality of first pads, the plurality of second pads, and the plurality of bonding wires.

The first and second detection circuits 10 and 20 each include a plurality of magnetic detection elements, and are configured to detect a target magnetic field and generate at least one detection signal. In particular, in the example embodiment, the plurality of magnetic detection elements are a plurality of magnetoresistive elements. Magnetoresistive elements will hereinafter be referred to as MR elements.

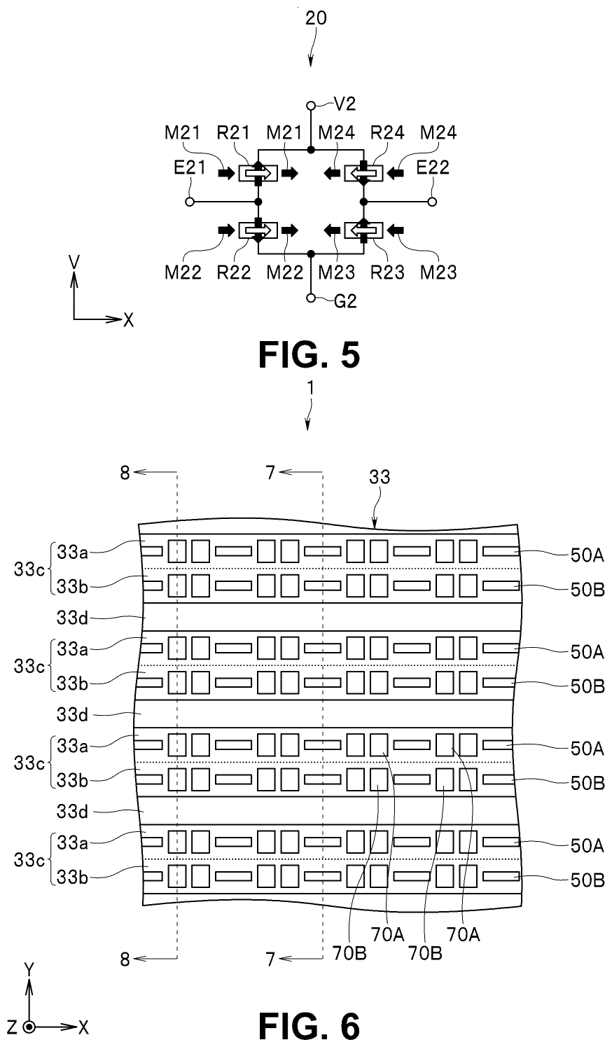

Hereinafter, circuit configurations of the first and second detection circuits 10 and 20 will be described with reference to FIGS. 4 and 5. FIG. 4 is a circuit diagram showing a circuit configuration of the first detection circuit 10. FIG. 5 is a circuit diagram showing a circuit configuration of the second detection circuit 20.

The first detection circuit 10 is configured to detect a component of the target magnetic field in a direction parallel to the U direction, and generate at least one first detection signal having a correspondence with the component. The second detection circuit 20 is configured to detect a component of the target magnetic field in a direction parallel to the V direction, and generate at least one second detection signal having a correspondence with the component.

As shown in FIG. 4, the first detection circuit 10 includes four resistor sections R11, R12, R13, and R14, a power supply port V1, a ground port G1, a first output port E11, and a second output port E12. A plurality of MR elements of the first detection circuit 10 constitute the resistor sections R11, R12, R13, and R14.

The first resistor section R11 is provided between the power supply port V1 and the first output port E11. The second resistor section R12 is provided between the first output port E11 and the ground port G1. The third resistor section R13 is provided between the second output port E12 and the ground port G1. The fourth resistor section R14 is provided between the power supply port V1 and the second output port E12.

As shown in FIG. 5, the second detection circuit 20 includes four resistor sections R21, R22, R23, and R24, a power supply port V2, a ground port G2, a first output port E21, and a second output port E22. A plurality of MR elements of the second detection circuit 20 constitute the resistor sections R21, R22, R23, and R24.

The resistor section R21 is provided between the power supply port V2 and the first output port E21. The resistor section R22 is provided between the first output port E21 and the ground port G2. The resistor section R23 is provided between the second output port E22 and the ground port G2. The resistor section R24 is provided between the power supply port V2 and the second output port E22.

A voltage or current of a specific magnitude is applied to each of the power supply ports V1 and V2. Each of the ground ports G1 and G2 is connected to the ground.

Hereinafter, the plurality of MR elements of the first detection circuit 10 will be referred to as a plurality of first MR elements 50A. The plurality of MR elements of the second detection circuit 20 will be referred to as a plurality of second MR elements 50B. Since the first and second detection circuits 10 and 20 are components of the magnetic sensor 1, it can be said that the magnetic sensor 1 includes the plurality of first MR elements 50A and the plurality of second MR elements 50B. Any given MR element will be denoted by the reference numeral 50.

In particular, in the example embodiment, the MR element 50 is a spin-valve MR element. The MR element 50 includes a magnetization pinned layer whose magnetization direction is fixed, a free layer whose magnetization direction is variable depending on the direction of a target magnetic field, and a gap layer disposed between the magnetization pinned layer and the free layer. The MR element 50 may be a tunneling magnetoresistive (TMR) element or a giant magnetoresistive (GMR) element. In the TMR element, the gap layer is a tunnel barrier layer. In the GMR element, the gap layer is a nonmagnetic conductive layer. The resistance of the MR element 50 changes with the angle that the magnetization direction of the free layer forms with the magnetization direction of the magnetization pinned layer. The resistance of the MR element 50 is at its minimum value when the foregoing angle is 0°, and at its maximum value when the foregoing angle is 180°. In each MR element 50, the free layer has a shape anisotropy that sets the direction of the magnetization easy axis to be orthogonal to the magnetization direction of the magnetization pinned layer.

In FIGS. 4 and 5, the plurality of solid arrows overlapping the respective resistor sections indicate the magnetization directions of the magnetization pinned layers of the MR elements 50. The plurality of hollow arrows overlapping the respective resistor sections indicate the magnetization directions of the free layers of the MR elements 50 when no target magnetic field is applied to the MR elements 50.

In the example shown in FIG. 4, the magnetization directions of the magnetization pinned layers in each of the resistor sections R11 and R13 are in the U direction. The magnetization directions of the magnetization pinned layers in each of the resistor sections R12 and R14 are in the −U direction. The free layer in each of the plurality of first MR elements 50A has a shape anisotropy that sets the direction of the magnetization easy axis to a direction parallel to the X direction. The magnetization directions of the free layers in each of the resistor sections R11 and R12 are in the X direction when no target magnetic field is applied to the first MR elements 50A. The magnetization directions of the free layers in each of the resistor sections R13 and R14 in the foregoing case are in the −X direction.

In the example shown in FIG. 5, the magnetization directions of the magnetization pinned layers in each of the resistor sections R21 and R23 are in the V direction. The magnetization directions of the magnetization pinned layers in each of the resistor sections R22 and R24 are in the −V direction. The free layer in each of the plurality of second MR elements 50B has a shape anisotropy that sets the direction of the magnetization easy axis to the direction parallel to the X direction. The magnetization directions of the free layers in each of the resistor sections R21 and R22 are in the X direction when no target magnetic field is applied to the second MR elements 50B. The magnetization directions of the free layers in each of the resistor sections R23 and R24 in the foregoing case are in the −X direction.

The magnetic sensor 1 further includes at least one magnetic field generator that generates a magnetic field to be applied to the at least one MR element 50. In particular, in the example embodiment, the magnetic sensor 1 includes a plurality of first magnetic field generators 70A and a plurality of second magnetic field generators 70B as the at least one magnetic field generator. Note that any given magnetic field generator will be denoted by the reference numeral 70.

In FIG. 4, the arrows denoted by the reference numerals M11, M12, M13, and M14 indicate the directions of the magnetic fields (bias magnetic fields) applied to the plurality of first MR elements 50A by the plurality of first magnetic field generators 70A. In the resistor sections R11 and R12, a magnetic field in the X direction is applied to the plurality of first MR elements 50A by the plurality of first magnetic field generators 70A. In the resistor sections R13 and R14, a magnetic field in the −X direction is applied to the plurality of first MR elements 50A by the plurality of first magnetic field generators 70A.

In FIG. 5, the arrows denoted by the reference numerals M21, M22, M23, and M24 indicate the directions of the magnetic fields (bias magnetic fields) applied to the plurality of second MR elements 50B by the plurality of second magnetic field generators 70B. In the resistor sections R21 and R22, a magnetic field in the X direction is applied to the plurality of second MR elements 50B by the plurality of second magnetic field generators 70B. In the resistor sections R23 and R24, a magnetic field in the −X direction is applied to the plurality of second MR elements 50B by the plurality of second magnetic field generators 70B.

Note that, in view of factors such as the production accuracy of the MR elements 50 and the magnetic field generators 70, the magnetization directions of the magnetization pinned layers, the directions of the magnetization easy axes of the free layers, and the directions of the magnetic fields applied to the MR elements 50 by the plurality of magnetic field generators 70 may be slightly different from the foregoing directions. The magnetization pinned layers may be configured to be magnetized to include magnetization components having the foregoing directions as their main components. In such a case, the magnetization directions of the magnetization pinned layers are the same or substantially the same as the foregoing directions.

Next, the first and second detection signals will be described. The first detection signal will initially be described with reference to FIG. 4. As the strength of the component of the target magnetic field in the direction parallel to the U direction changes, the resistance of each of the resistor sections R11 to R14 of the first detection circuit 10 changes either so that the resistances of the resistor sections R11 and R13 increase and the resistances of the resistor sections R12 and R14 decrease, or so that the resistances of the resistor sections R11 and R13 decrease and the resistances of the resistor sections R12 and R14 increase. Thereby the electric potential at each of the first and second signal output ports E11 and E12 changes. The first detection circuit 10 is configured to generate a signal corresponding to the electric potential at the first output port E11 as a first detection signal S11, and generate a signal corresponding to the electric potential at the second output port E12 as a first detection signal S12.

Next, a second detection signal will be described with reference to FIG. 5. As the strength of the component of the target magnetic field in the direction parallel to the V direction changes, the resistance of each of the resistor sections R21 to R24 of the second detection circuit 20 changes either so that the resistances of the resistor sections R21 and R23 increase and the resistances of the resistor sections R22 and R24 decrease, or so that the resistances of the resistor sections R21 and R23 decrease and the resistances of the resistor sections R22 and R24 increase. Thereby the electric potential at each of the first and second output ports E21 and E22 changes. The second detection circuit 20 is configured to generate a signal corresponding to the electric potential at the first output port E21 as a second detection signal S21, and generate a signal corresponding to the electric potential at the second output port E22 as a second detection signal S22.

Next, the operation of the processor 2 will be described. The processor 2 is configured to generate a first detection value and a second detection value based on the first detection signals S11 and S12, and the second detection signals S21 and S22. The first detection value is a detection value corresponding to the component of the target magnetic field in a direction parallel to the Y direction. The second detection value is a detection value corresponding to the component of the target magnetic field in a direction parallel to the Z direction. Hereinafter, the first detection value is represented by the symbol Sy, and the second detection value is represented by the symbol Sz.

The processor 2 generates the first and second detection values Sy and Sz as follows, for example. First, the processor 2 generates a value S1 by an arithmetic including obtainment of a difference S11-S12 between the first detection signal S11 and the first detection signal S12, and generates a value S2 by an arithmetic including obtainment of a difference S21-S22 between the second detection signal S21 and the second detection signal S22. Next, the processor 2 calculates values S3 and S4 using the following expressions (1) and (2).

$$S 3 = ( S 2 + S 1 ) / ( 2 cos α ) \qquad ( 1 )$$

$$S 4 = ( S 2 - S 1 ) / ( 2 sin α ) \qquad ( 2 )$$

The first detection value Sy may be the value S3 itself, or may be a result of corrections, such as a gain adjustment and an offset adjustment, made to the value S3. In the same manner, the second detection value Sz may be the value S4 itself, or may be a result of corrections, such as a gain adjustment and an offset adjustment, made to the value S4.

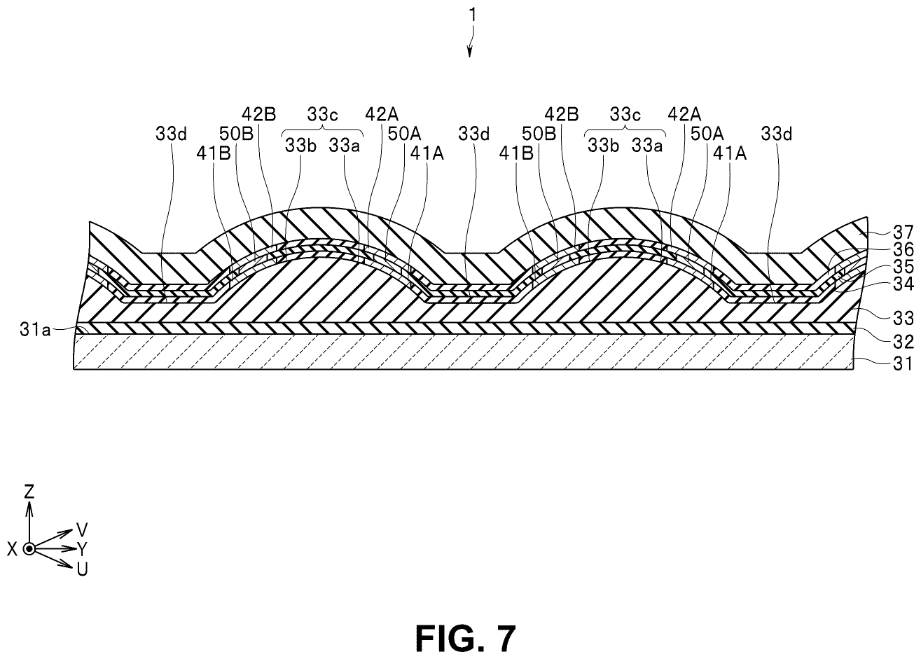

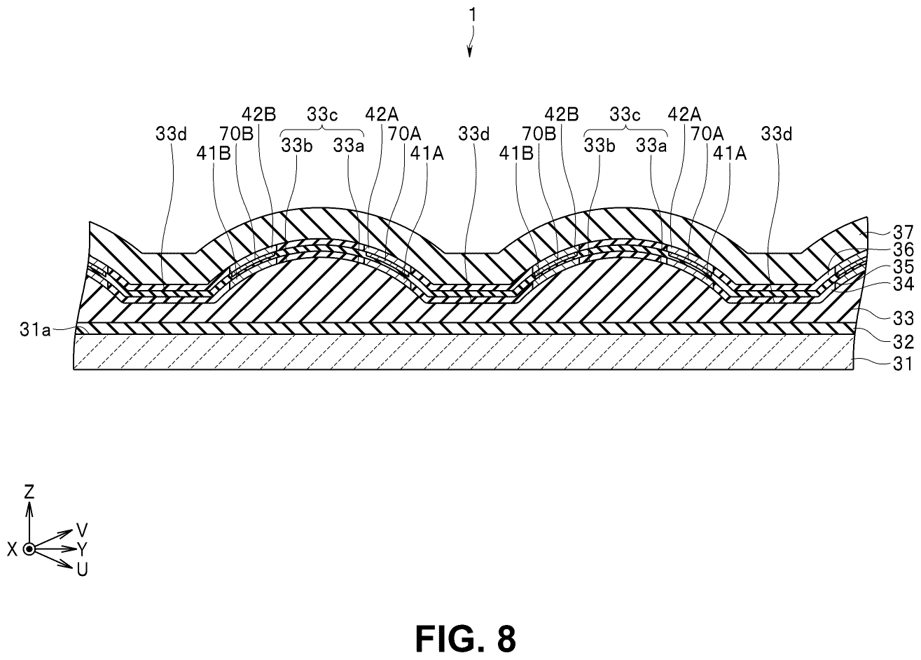

Next, the specific structure of the magnetic sensor 1 will be described in detail with reference to FIGS. 6 through 8. FIG. 6 is a plan view showing a part of the magnetic sensor 1. FIG. 7 shows a part of a cross section at a position indicated by the line 7-7 in FIG. 6. FIG. 8 shows a part of a cross section at a position indicated by the line 8-8 in FIG. 6.

The magnetic sensor 1 includes a substrate 31 including a top surface 31a, insulating layers 32, 33, 34, 35, 36, and 37, a plurality of lower electrodes 41A, a plurality of lower electrodes 41B, a plurality of upper electrodes 42A, and a plurality of upper electrodes 42B. The top surface 31a of the substrate 31 is parallel to an XY plane. The Z direction is one direction perpendicular to the top surface 31a of the substrate 31. The top surface 31a of the substrate 31 corresponds to the “reference plane” in the disclosure.

The insulating layers 32 and 33 are disposed in this order on the substrate 31. The plurality of lower electrodes 41A and the plurality of lower electrodes 41B are disposed on the insulating layer 33. The insulating layer 34 is disposed around the plurality of lower electrodes 41A and around the plurality of lower electrodes 41B on the insulating layer 33. The plurality of first MR elements 50A are disposed on the plurality of lower electrodes 41A. The plurality of second MR elements 50B are disposed on the plurality of lower electrodes 41B. The insulating layer 35 is disposed around the plurality of first MR elements 50A and around the plurality of second MR elements 50B on the plurality of lower electrodes 41A, the plurality of lower electrodes 41B, and the insulating layer 34. The plurality of upper electrodes 42A are disposed on the plurality of first MR elements 50A and the insulating layer 35. The plurality of upper electrodes 42B are disposed on the plurality of second MR elements 50B and the insulating layer 35. The insulating layer 36 is disposed around the plurality of upper electrodes 42A and around the plurality of upper electrodes 42B on the insulating layer 35. The insulating layer 37 is disposed on the plurality of upper electrodes 42A, the plurality of upper electrodes 42B, and the insulating layer 36.

The plurality of first magnetic field generators 70A and the plurality of second magnetic field generators 70B are embedded in the insulating layer 35. Each of the plurality of first magnetic field generators 70A is disposed at distances from the first MR elements 50A and the lower electrodes 41A. Each of the plurality of second magnetic field generators 70B is disposed at distances from the second MR elements 50B and the lower electrodes 41B. The magnetic sensor 1 may further include insulating films interposed between each of the plurality of first magnetic field generators 70A and each of the plurality of first MR elements 50A, between each of the plurality of second magnetic field generators 70B and each of the plurality of second MR elements 50B, between each of the plurality of first magnetic field generators 70A and each of the plurality of lower electrodes 41A, and between each of the plurality of second magnetic field generators 70B and each of the plurality of lower electrodes 41B.

The top surface of each of the plurality of first magnetic field generators 70A may be in contact with the bottom surfaces of the plurality of upper electrodes 42A. The top surface of each of the plurality of second magnetic field generators 70B may be in contact with the bottom surfaces of the plurality of upper electrodes 42B.

The magnetic sensor 1 includes a support member that supports the plurality of first MR elements 50A and the plurality of second MR elements 50B. The support member includes at least one inclined surface inclined relative to the top surface 31a of the substrate 31. In particular, in the example embodiment, the support member includes the insulating layer 33. Note that FIG. 6 shows, among the components of the magnetic sensor 1, the insulating layer 33, the plurality of first MR elements 50A, the plurality of second MR elements 50B, the plurality of first magnetic field generators 70A, and the plurality of second magnetic field generators 70B.

The insulating layer 33 includes a plurality of protruding surfaces 33c each protruding in a direction away from the top surface 31a of the substrate 31 (Z direction). Each of the plurality of protruding surfaces 33c extends in the direction parallel to the X direction. The overall shape of the protruding surface 33c is a semi-cylindrical curved surface obtained by moving the curved shape (arch shape) of the protruding surface 33c shown in FIGS. 7 and 8 along the direction parallel to the X direction. The plurality of protruding surfaces 33c are arranged in the direction parallel to the Y direction at specific intervals.

Each of the plurality of protruding surfaces 33c has an upper end section farthest from the top surface 31a of the substrate 31. In the example embodiment, the upper end section of each of the plurality of protruding surfaces 33c is assumed to extend in the direction parallel to the X direction. Now, focus is placed on any one of the plurality of protruding surfaces 33c. The protruding surface 33c includes a first inclined surface 33a and a second inclined surface 33b. The first inclined surface 33a is a surface of the protruding surface 33c that is on the Y direction side of the protruding surface 33c with respect to the upper end section of the protruding surface 33c. The second inclined surface 33b is a surface of the protruding surface 33c that is on the −Y direction side of the protruding surface 33c with respect to the upper end section of the protruding surface 33c. In FIG. 6, the boundary between the first inclined surface 33a and the second inclined surface 33b is indicated by a dotted line.

The upper end section of the protruding surface 33c may be the boundary between the first inclined surface 33a and the second inclined surface 33b. In such a case, the dotted line shown in FIG. 6 indicates the upper end section of the protruding surface 33c.

The top surface 31a of the substrate 31 is parallel to the XY plane. The first inclined surface 33a and the second inclined surface 33b are each inclined relative to the top surface 31a of the substrate 31, i.e., the XY plane. In a cross section perpendicular to the top surface 31a of the substrate 31, the distance between the first inclined surface 33a and the second inclined surface 33b becomes smaller in a direction away from the top surface 31a of the substrate 31.

In the example embodiment, due to the presence of the plurality of protruding surfaces 33c, there are a plurality of first inclined surfaces 33a and a plurality of second inclined surfaces 33b. The insulating layer 33 includes the plurality of first inclined surfaces 33a and the plurality of second inclined surfaces 33b.

The insulating layer 33 further includes a flat surface 33d present around the plurality of protruding surfaces 33c. The flat surface 33d is a surface parallel to the top surface 31a of the substrate 31. Each of the plurality of protruding surfaces 33c protrudes in the Z direction from the flat surface 33d. In the example embodiment, the plurality of protruding surfaces 33c are disposed at a specific distance. Therefore, the flat surface 33d is present between two protruding surfaces 33c adjacent in the Y direction.

The insulating layer 33 may include groove portions recessed in the −Z direction from the flat surface 33d. In such a case, the plurality of protruding surfaces 33c may be present in the groove portions.

The plurality of lower electrodes 41A are disposed on the plurality of first inclined surfaces 33a. The plurality of lower electrodes 41B are disposed on the plurality of second inclined surfaces 33b. As mentioned above, the first and second inclined surfaces 33a and 33b are each inclined relative to the top surface 31a of the substrate 31, i.e., the reference plane. Therefore, the top surface of each of the plurality of lower electrodes 41A and the top surface of each of the plurality of lower electrode 41B are also inclined relative to the reference plane. Thus, it can be said that the plurality of first MR elements 50A and the plurality of second MR elements 50B are disposed on the inclined surfaces inclined relative to the reference plane. The insulating layer 33 is a member for supporting each of the plurality of first MR elements 50A and the plurality of second MR elements 50B so as to allow each of the MR elements to be inclined relative to the reference plane.

In the example embodiment, the first inclined surface 33a is a curved surface. The first MR element 50A is curved along the curved surface (first inclined surface 33a). Even in such a case, the magnetization direction of the magnetization pinned layer of the first MR element 50A is defined as a straight direction for convenience sake. In the same manner, in the example embodiment, the second inclined surface 33b is a curved surface. The second MR element 50B is curved along the curved surface (second inclined surface 33b). Even in such a case, the magnetization direction of the magnetization pinned layer of the second MR element 50B is defined as a straight direction for convenience sake.

The plurality of first magnetic field generators 70A are substantially disposed on the plurality of first inclined surfaces 33a. Each of the plurality of first magnetic field generators 70A has a bottom surface having a shape along the first inclined surface 33a.

The plurality of second magnetic field generators 70B are substantially disposed on the plurality of second inclined surfaces 33b. Each of the plurality of second magnetic field generators 70B has a bottom surface having a shape along the second inclined surface 33b.

Now, focus is placed on any given one of the plurality of first magnetic field generators 70A and any given one of the plurality of second magnetic field generators 70B. As shown in FIG. 6, the plurality of first magnetic field generators 70A are arranged several in rows in both the X and Y directions. Each of the plurality of first MR elements 50A is disposed between two first magnetic field generators 70A adjacent in the direction parallel to the X direction. Several first MR elements 50A and several first magnetic field generators 70A are arranged in a row on one first inclined surface 33a.

In the example shown in FIG. 6, two first magnetic field generators 70A are disposed between two first MR elements 50A adjacent in the direction parallel to the X direction. Note that the number of the first magnetic field generators 70A disposed between the two first MR elements 50A is not limited to two, but may be one.

In the same manner, the plurality of second magnetic field generators 70B are arranged several in rows in both the X and Y directions. Each of the plurality of second MR elements 50B is located between two second magnetic field generators 70B adjacent in the direction parallel to the X direction. Several second MR elements 50B and several second magnetic field generators 70B are arranged in a row on one second inclined surface 33b.

In the example shown in FIG. 6, two second magnetic field generators 70B are disposed between two second MR elements 50B adjacent in the direction parallel to the X direction. Note that the number of the second magnetic field generators 70B disposed between the two second MR elements 50B is not limited to two, but may be one.

The rows of the several first MR elements 50A and the several first magnetic field generators 70A and the rows of the several second MR elements 50B and the several second magnetic field generators 70B are alternately arranged in the direction parallel to the Y direction.

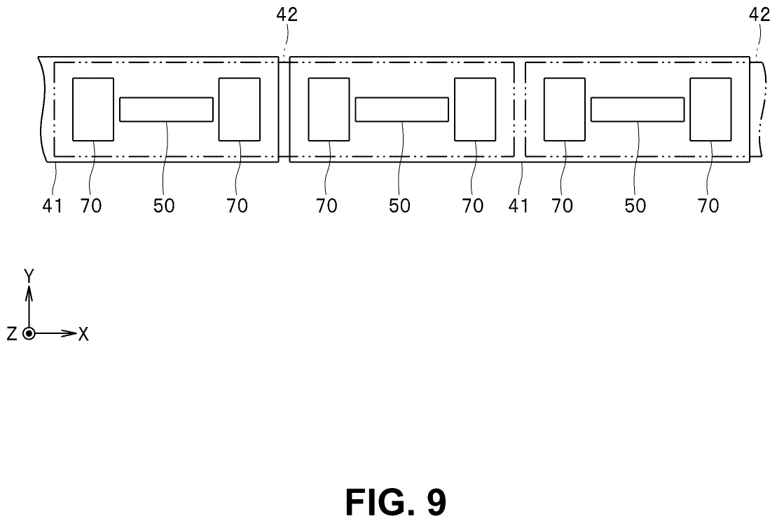

The plurality of first MR elements 50A are connected in series by the plurality of lower electrodes 41A and the plurality of upper electrodes 42A. A method for connecting the plurality of first MR elements 50A will now be described in detail with reference to FIG. 9. In FIG. 9, the reference numerals 41 denote lower electrodes corresponding to given MR elements 50, and the reference numerals 42 denote upper electrodes corresponding to the given MR elements 50.

As shown in FIG. 9, each lower electrode 41 has a long slender shape. Two lower electrodes 41 adjacent in the longitudinal direction of the lower electrodes 41 have a gap therebetween. The MR elements 50 are disposed near both longitudinal ends on the top surface of the each lower electrode 41. Each upper electrode 42 has a long slender shape, and electrically connects two adjacent MR elements 50 that are disposed on the two lower electrodes 41 adjacent in the longitudinal direction of the lower electrodes 41.

At least one magnetic field generator 70 is disposed between the two MR elements 50 adjacent in the longitudinal direction of the lower electrodes 41. FIG. 9 shows an example where two magnetic field generators 70 are disposed between the two MR elements 50. However, one magnetic field generator 70 may be disposed between the two MR elements 50. The magnetic field generator 70 may or may not be in contact with the upper electrode 42.

Although not shown in the drawings, one MR element 50 located at the end of a row of several MR elements 50 is connected to another one of the MR element 50 located at the end of another row of several MR elements 50 adjacent in a direction intersecting the longitudinal direction of the lower electrodes 41. The two MR elements 50 are connected to each other by a not-shown electrode. The not-shown electrode may be an electrode connecting the bottom surfaces or the top surfaces of the two MR elements 50.

If the MR elements 50 in FIG. 9 are the first MR elements 50A, the lower electrodes 41, the upper electrodes 42, and the magnetic field generators 70 in FIG. 9 correspond to the lower electrodes 41A, the upper electrodes 42A, and the first magnetic field generators 70A, respectively. If the MR elements 50 in FIG. 9 are the second MR elements 50B, the lower electrodes 41, the upper electrodes 42, and the magnetic field generators 70 in FIG. 9 correspond to the lower electrodes 41B, the upper electrodes 42B, and the second magnetic field generators 70B, respectively.

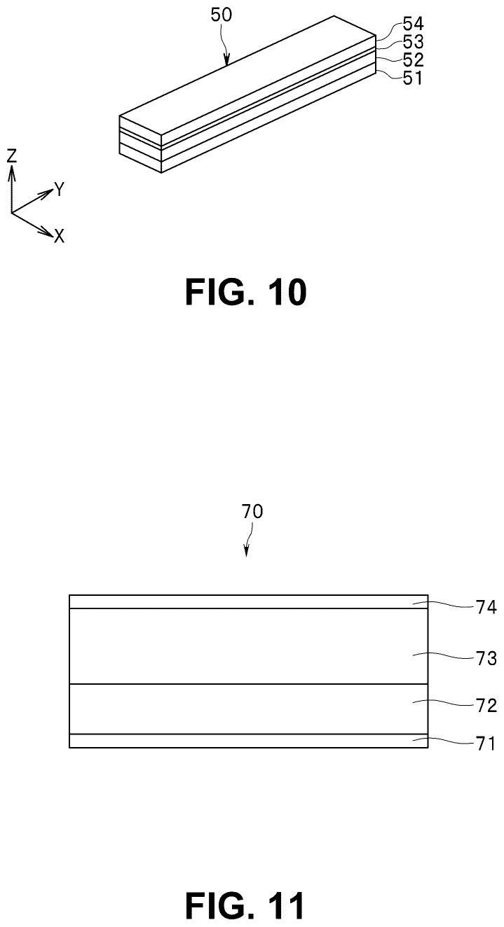

Next, a configuration of the MR elements 50 will be described in more detail with reference to FIG. 10. In FIG. 10, the reference numeral 52 denotes the magnetization pinned layer, the reference numeral 53 the gap layer, and the reference numeral 54 the free layer. The MR element 50 further includes an antiferromagnetic layer 51. The antiferromagnetic layer 51, the magnetization pinned layer 52, the gap layer 53, and the free layer 54 are stacked in this order from the lower electrode 41 to the upper electrode 42. The antiferromagnetic layer 51 is formed of an antiferromagnetic material, and is in exchange coupling with the magnetization pinned layer 52 to thereby pin the magnetization direction of the magnetization pinned layer 52. The magnetization pinned layer 52 may be a so-called self-pinned layer (Synthetic Ferri Pinned layer, SFP layer). The self-pinned layer has a stacked ferri-structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

Note that the layers 51 to 54 of each MR element 50 may be stacked in the reverse order to that shown in FIG. 10.

In the first MR element 50A, the antiferromagnetic layer 51, the magnetization pinned layer 52, the gap layer 53, and the free layer 54 are stacked in a direction intersecting the first inclined surface 33a (see FIGS. 6 and 7). This direction may be a direction perpendicular to the first inclined surface 33a.

In the second MR element 50B, the antiferromagnetic layer 51, the magnetization pinned layer 52, the gap layer 53, and the free layer 54 are stacked in a direction intersecting the second inclined surface 33b (see FIGS. 6 and 7). This direction may be a direction perpendicular to the second inclined surface 33b.

Next, a configuration of the magnetic field generator 70 will be described with reference to FIG. 11. FIG. 11 is a side view showing the magnetic field generator 70. The magnetic field generator 70 may include a ferromagnetic portion 73 and an antiferromagnetic portion 72 that is in contact with the ferromagnetic portion 73 and is in exchange coupling with the ferromagnetic portion 73.

The ferromagnetic portion 73 has its overall magnetization. The overall magnetization of the ferromagnetic portion 73 refers to the volume average of the vector sum of magnetic moments in units of atoms, crystal lattices, or the like in the entire ferromagnetic portion 73. Hereinafter, the overall magnetization of the ferromagnetic portion 73 will simply be referred to as the magnetization of the ferromagnetic portion 73.

In the magnetic field generator 70, the magnetization direction of the

ferromagnetic portion 73 is defined by exchange coupling between the antiferromagnetic portion 72 and the ferromagnetic portion 73. The ferromagnetic portion 73 and the antiferromagnetic portion 72 generate a magnetic field to be applied to the MR element 50, based on the magnetization of the ferromagnetic portion 73. The magnetic field generator 70 thus constituted is highly resistant to disturbance magnetic fields.

The ferromagnetic portion 73 is formed of a ferromagnetic material containing one or more elements selected from the group consisting of Co, Fe, and Ni. Examples of such a ferromagnetic material include CoFe, CoFeB, and CoNiFe. The antiferromagnetic portion 72 is formed of an antiferromagnetic material such as IrMn or PtMn.

The magnetic field generator 70 further includes a buffer layer 71 and a cap layer 74. The buffer layer 71, the antiferromagnetic portion 72, the ferromagnetic portion 73, and the cap layer 74 are stacked in this order. Each of the buffer layer 71 and the cap layer 74 is formed of a nonmagnetic metallic material such as, for example, Ru, Ta, Cu, or Cr.

Now, with reference to FIGS. 8 and 11, the stacking direction and bottom surfaces of the antiferromagnetic portion 72 and the ferromagnetic portion 73 of the first and second magnetic field generators 70A and 70B will be described. In the first magnetic field generator 70A, the antiferromagnetic portion 72 and the ferromagnetic portion 73 are stacked in a direction intersecting the first inclined surface 33a. This direction may be a direction perpendicular to the first inclined surface 33a. The antiferromagnetic portion 72 and the ferromagnetic portion 73 each have a bottom surface facing the first inclined surface 33a and inclined relative to the top surface 31a of the substrate 31, i.e., the reference plane. Such a bottom surface can be implemented by forming each of the buffer layer 71 and the antiferromagnetic portion 72 in such a thickness that the shape of the first inclined surface 33a appears.

In the second magnetic field generator 70B, the antiferromagnetic portion 72 and the ferromagnetic portion 73 are stacked in a direction intersecting the second inclined surface 33b. This direction may be a direction perpendicular to the second inclined surface 33b. The antiferromagnetic portion 72 and the ferromagnetic portion 73 each have a bottom surface facing the second inclined surface 33b and inclined relative to the top surface 31a of the substrate 31, i.e., the reference plane. Such a bottom surface can be implemented by forming each of the buffer layer 71 and the antiferromagnetic portion 72 in such a thickness that the shape of the second inclined surface 33b appears.

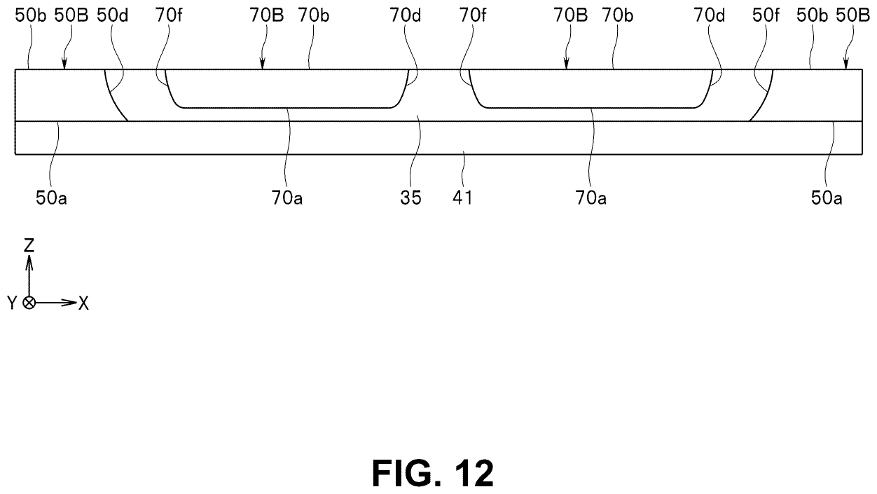

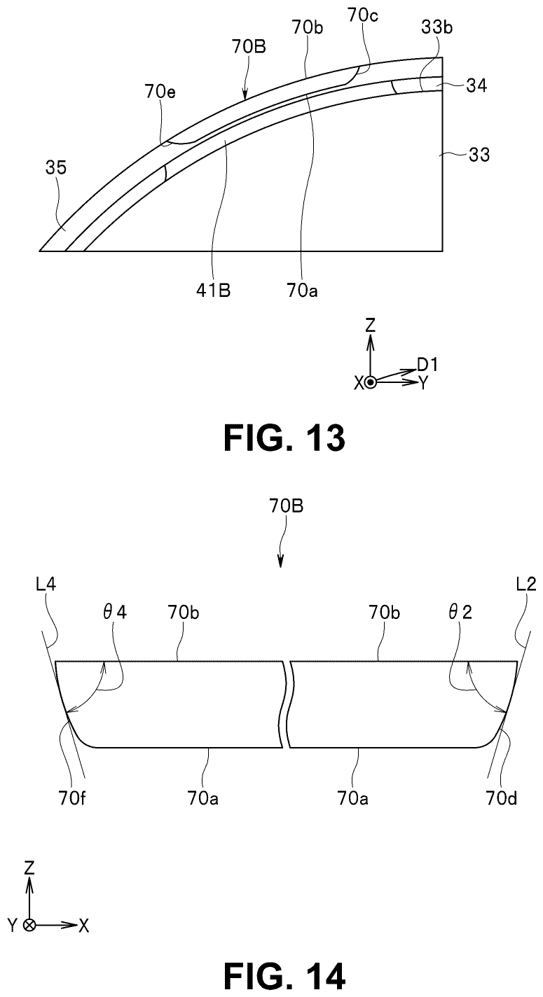

Next, features of the shape and disposition of the MR element 50 and the magnetic field generator 70 will be described with reference to FIGS. 6 through 9, 12, and 13. FIGS. 12 and 13 are each a cross-sectional view showing a part of the magnetic sensor 1. FIG. 12 shows a cross section that is parallel to the XZ plane and perpendicular to the top surface 31a of the substrate 31, and that intersects the second MR element 50B and the second magnetic field generator 70B. FIG. 13 shows a cross section parallel to the YZ plane and intersecting the second magnetic field generator 70B. The cross section shown in FIG. 12 corresponds to a “second cross section” in the disclosure. The cross section shown in FIG. 13 is perpendicular to each of the top surface 31a of the substrate 31 and the cross section shown in FIG. 12, and corresponds to a “first cross section” in the disclosure.

Hereinafter, even when descriptions are made with reference to FIGS. 12 and 13, features common to the first MR element 50A and the second MR element 50B will be described as features of the MR element 50, and features common to the first magnetic field generator 70A and the second magnetic field generator 70B will be described as features of the magnetic field generator 70.

The magnetic field generator 70 is disposed at a distance from the MR element 50. The insulating layer 35 is interposed between the MR element 50 and the magnetic field generator 70.

The dimension of the magnetic field generator 70 in the direction parallel to the Y direction is greater than that of the MR element 50 in the direction parallel to the Y direction. When viewed in the X direction, at least a part of the MR element 50 overlaps at least a part of the magnetic field generator 70. In particular, in the example embodiment, when viewed in the X direction, at least a part of the free layer 54 of the MR element 50 overlaps at least a part of the ferromagnetic portion 73 of the magnetic field generator 70.

Now, a first direction D1 parallel to the YZ plane will be defined as shown in FIG. 13. The first direction D1 is a direction along the first inclined surface 33a or the second inclined surface 33b and away from the top surface 31a of the substrate 31. If the first direction D1 is defined as a direction along the second inclined surface 33b as shown in FIG. 13, the first direction D1 is a direction between the Y direction and the Z direction. Although not shown in the drawing, if the first direction D1 is defined as a direction along the first inclined surface 33a, the first direction D1 is a direction between the −Y direction and the Z direction.

In the following description, a direction along the first inclined surface 33a or the second inclined surface 33b and parallel to the first direction D1 is simply referred to as a direction along the inclined surface. This direction is also a direction along the inclined surface and a direction in which the distance from the top surface 31a of the substrate 31 changes.

The MR element 50 includes a bottom surface 50a facing the first inclined surface 33a or the second inclined surface 33b, a top surface 50b opposite the bottom surface 50a, and a side surface connecting the bottom surface 50a and the top surface 50b. The side surface of the MR element 50 includes a first part located at the end in the first direction D1, a second part 50d located at the end in the X direction, a third part located opposite to the first part, and a fourth part 50f located opposite to the second part 50d. In particular, in the example embodiment, the first part, the second part 50d, the third part, and the fourth part 50f of the side surface of the MR element 50 are all located above the first inclined surface 33a or the second inclined surface 33b.

As shown in FIG. 12, each of the second part 50d and the fourth part 50f of the side surface of the MR element 50 is inclined relative to the top surface 31a of the substrate 31. In one MR element 50, the distance between the second part 50d and the fourth part 50f in the direction parallel to the X direction decreases with increasing distance from the top surface 31a of the substrate 31. Although not shown in the drawing, each of the first part and the third part of the side surface of the MR element 50 is inclined relative to the top surface 31a of the substrate 31. In one MR element 50, the distance between the first part and the third part in the direction along the inclined surface may decrease with increasing distance from the first inclined surface 33a or the second inclined surface 33b located below the MR element 50.

Note that the first part of the side surface of the first MR element 50A is located at the end of the first MR element 50A in the −Y direction. The first part of the side surface of the second MR element 50B is located at the end of the second MR element 50B in the Y direction.

The magnetic field generator 70 includes a bottom surface 70a facing the first inclined surface 33a or the second inclined surface 33b, a top surface 70b opposite the bottom surface 70a, and a side surface connecting the bottom surface 70a and the top surface 70b. The side surface of the magnetic field generator 70 includes a first part 70c located at the end in the first direction D1, a second part 70d located at the end in the X direction, a third part 70e located opposite the first part 70c, and a fourth part 70f located opposite the second part 70d. In particular, in the example embodiment, the first through fourth parts 70c to 70f of the side surface of the magnetic field generator 70 are all located above the first inclined surface 33a or the second inclined surface 33b.

As shown in FIG. 12, each of the second part 70d and the fourth part 70f of the side surface of the magnetic field generator 70 is inclined relative to the top surface 31a of the substrate 31. In one magnetic field generator 70, the distance between the second part 70d and the fourth part 70f in the direction parallel to the X direction increases with increasing distance from the top surface 31a of the substrate 31. As shown in FIG. 13, each of the first part 70c and the third part 70e of the side surface of the magnetic field generator 70 is inclined relative to the top surface 31a of the substrate 31. In one magnetic field generator 70, the distance between the first part 70c and the third part 70e in the direction along the inclined surface increases with increasing distance from the first inclined surface 33a or the second inclined surface 33b located below the magnetic field generator 70.

Note that the first part 70c of the side surface of the first magnetic field generator 70A is located at the end of the first magnetic field generator 70A in the −Y direction. The first part 70c of the side surface of the second magnetic field generator 70B is located at the end of the second magnetic field generator 70B in the Y direction.

Each of the insulating layers 34 and 35 may include a part interposed between the first inclined surface 33a or the second inclined surface 33b and the first part 70c of the side surface of the magnetic field generator 70, a part interposed between the first inclined surface 33a or the second inclined surface 33b and the second part 70d of the side surface of the magnetic field generator 70, a part interposed between the first inclined surface 33a or the second inclined surface 33b and the third part 70e of the side surface of the magnetic field generator 70, and a part interposed between the first inclined surface 33a or the second inclined surface 33b and the fourth part 70f of the side surface of the magnetic field generator 70.

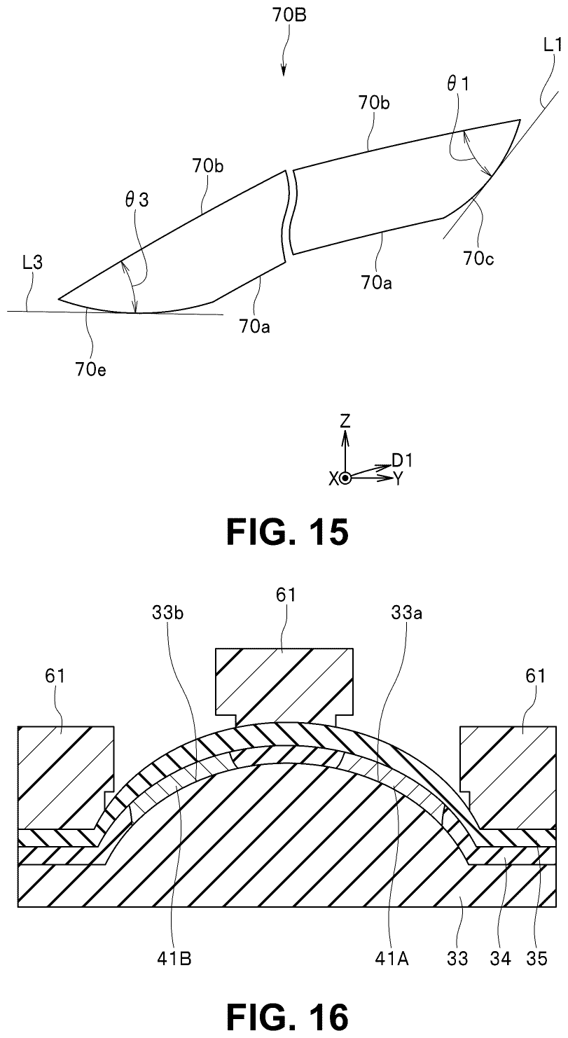

Next, shapes of the first through fourth parts 70c to 70f of the side surface of the magnetic field generator 70 will be described with reference to FIGS. 14 and 15. FIGS. 14 and 15 are each an explanatory diagram for describing a shape of the side surface of the magnetic field generator 70. Note that FIG. 14 is a view showing, in an enlarged manner, a part of the second magnetic field generator 70B shown in FIG. 12. FIG. 15 is a view showing, in an enlarged manner, a part of the second magnetic field generator 70B shown in FIG. 13. In the same manner as FIGS. 12 and 13, even when descriptions are made with reference to FIGS. 14 and 15, features common to the first magnetic field generator 70A and the second magnetic field generator 70B will be described as features of the magnetic field generator 70.

Here, an angle that each of the first through fourth parts 70c to 70f of the side surface of the magnetic field generator 70 forms with the top surface 70b of the magnetic field generator 70 will be described. As shown in FIG. 15, in a cross section parallel to the YZ plane (first cross section), a first angle θ1 is the angle that the first part 70c forms with the top surface 70b, and a third angle θ3 is the angle that the third part 70e forms with the top surface 70b. As shown in FIG. 14, in a cross section parallel to the XZ plane (second cross section), a second angle θ2 is the angle that the second part 70d forms with the top surface 70b, and a fourth angle θ4 is the angle that the fourth part 70f forms with the top surface 70b.

The first angle θ1 is defined as an angle representing the overall shape of the first part 70c. The first angle θ1 may be the angle formed between the tangent line of the first part 70c and the top surface 70b in the first cross section. This tangent line may, for example, be tangent to the first part 70c at or near the center in a thickness direction of the magnetic field generator 70 (direction perpendicular to the first inclined surface 33a or the second inclined surface 33b). In FIG. 15, the straight line denoted with the reference numeral L1 indicates a tangent line tangent to the first part 70c at or near the center in the thickness direction of the magnetic field generator 70. Alternatively, a plurality of tangent lines tangent to the first part 70c at a plurality of positions of the first part 70c may be defined, and an average of a plurality of angles formed between the plurality of tangent lines and the top surface 70b may be the first angle θ1. Alternatively, the first angle θ1 may be an angle formed between a straight line approximating the shape of the first part 70c in the first cross section and the top surface 70b. Alternatively, the first angle θ1 may be an angle formed between a straight line connecting an upper end and a lower end of the first part 70c in the first cross section and the top surface 70b. Alternatively, an average value of a plurality of first angles θ1 defined by the plurality of methods described above may be used as the first angle θ1.

Note that the first angle θ1 is defined based on a shape of the top surface 70b at a part near the first part 70c. The first angle θ1 may be defined by considering the above-described part of the top surface 70b as a straight line. Alternatively, the first angle θ1 may be defined based on a straight line tangent to a position where the above-described part of the top surface 70b or the first part 70c intersects.

The above description of the first angle θ1 also applies to the third angle θ3. If the first angle θ1, the first part 70c, and the reference numeral L1 in the description of the first angle θ1 are replaced with the third angle θ3, the third part 70e, and the reference numeral L3, respectively, a description of the third angle θ3 is obtained.

The above description of the first angle θ1 also applies to the second and fourth angles θ2 and θ4. If the first angle θ1, the first part 70c, the reference numeral L1, the first cross section, and FIG. 15 in the description of the first angle θ1 are replaced with the second angle θ2, the second part 70d, the reference numeral L2, the second cross section, and FIG. 14, respectively, a description of the second angle θ2 is obtained. In the same manner, if the first angle θ1, the first part 70c, the reference numeral L1, the first cross section, and FIG. 15 in the description of the first angle θ1 are replace with the fourth angle θ4, the fourth part 70f, the reference numeral L4, the second cross section, and FIG. 14, respectively, a description of the fourth angle θ4 is obtained.

The relationship between the first through fourth angles θ1 to θ4 will be described below. The second angle θ2 is greater than the first angle θ1. The first angle θ1 may be greater than ½ of the second angle θ2, and the closer to the second angle θ2, the better.

The third angle θ3 may be greater than the first angle θ1. The first angle θ1 may be greater than ½ of the third angle θ3.

The fourth angle θ4 is the same or nearly the same as the second angle θ2. The relationship between the first angle θ1 and the second angle θ2 also applies to the first angle θ1 and the fourth angle θ4.

Next, a manufacturing method of the magnetic sensor 1 in the example embodiment will be briefly described. The process of manufacturing the magnetic sensor 1 includes a process of forming the insulating layer 33 as a support member, a process of forming a plurality of MR elements 50, and a process of forming the plurality of magnetic field generators 70. The plurality of MR elements 50 and the plurality of magnetic field generators 70 are formed on the insulating layer 33.

Initially, the process of forming of the plurality of MR elements 50 will be described. In the process of forming the plurality of MR elements 50, first, a plurality of initial MR elements to later become the plurality of MR elements 50 are formed. Each of the plurality of initial MR elements includes an initial magnetization pinned layer to later become the magnetization pinned layer 52, the antiferromagnetic layer 51, the gap layer 53, and the free layer 54.

Next, the magnetization direction of the initial magnetization pinned layer is fixed using laser light and an external magnetic field including a component in a specific direction. For example, in the plurality of initial MR elements to later become the plurality of first MR elements 50A constituting the resistor sections R11 and R13 of the first detection circuit 10, the plurality of initial MR elements are irradiated with laser light while an external magnetic field in the Y direction is applied thereto. The irradiation of the laser light is performed so that the temperature of the plurality of initial MR elements irradiated with the laser light becomes equal to or higher than a blocking temperature of the antiferromagnetic layer 51. The temperature of the plurality of initial MR elements can be adjusted, for example, by the intensity and pulse width of the laser light.

The external magnetic field in the Y direction can be divided into a component in the U direction and a component in a direction orthogonal to the U direction. After the irradiation of the laser light, when the temperature of the plurality of initial MR elements becomes lower than the blocking temperature, the magnetization directions of the initial magnetization pinned layers are fixed in the U direction. This causes the initial magnetization pinned layers to become the magnetization pinned layers 52, and the initial MR elements to become the first MR elements 50A.

In the plurality of initial MR elements to later become the plurality of first MR elements 50A constituting the resistor sections R12 and R14 of the first detection circuit 10, the magnetization direction of the initial magnetization pinned layer of each of the plurality of initial MR elements can be fixed in the −U direction by using an external magnetic field in the −Y direction. The plurality of first MR elements 50A are thus formed. The magnetization direction of the magnetization pinned layer 52 of each of the plurality of second MR elements 50B constituting each of the resistor sections R21 to R24 of the second detection circuit 20 is also fixed by the same method as with the magnetization pinned layer 52 of each of the plurality of first MR elements 50A.

The MR element 50 is completed by patterning a stacked film by etching so that the side surface of the MR element 50 is formed on the stacked film, after the magnetization direction of the magnetization pinned layer 52 is fixed. Note that the process of fixing the magnetization directions of the initial magnetization pinned layers may be performed after the side surface of the MR element 50 is formed on the stacked film. Next, the insulating layer 35 is formed around the plurality of first MR elements 50A and the plurality of second MR elements 50B.

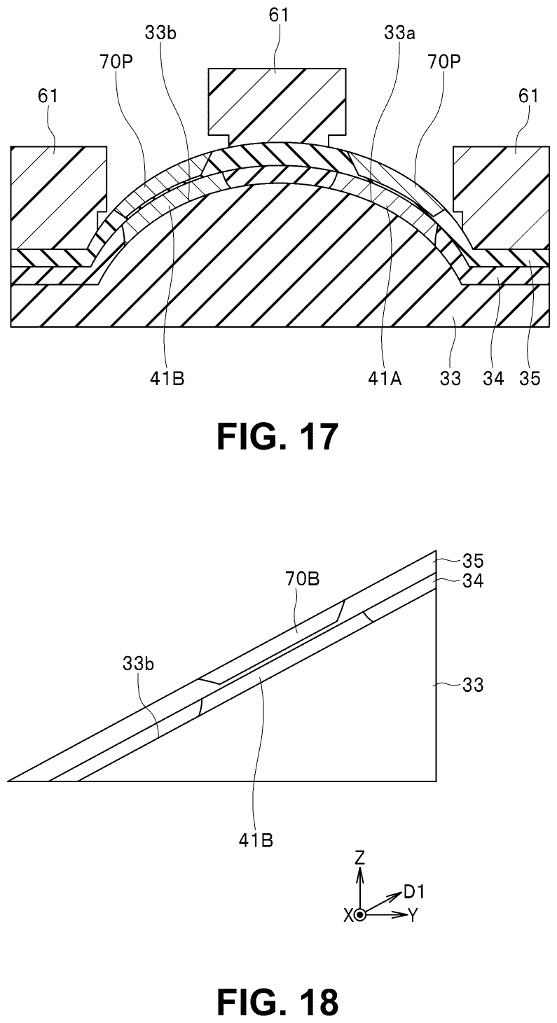

Next, a process of forming the plurality of magnetic field generators 70 will be described with reference to FIGS. 16 and 17. FIGS. 16 and 17 each show a stack in the manufacturing process of the magnetic sensor 1. The process of forming the plurality of magnetic field generators 70 may be performed after the plurality of MR elements 50 and the insulating layer 35 are formed. The insulating layer 35 is formed around the plurality of MR elements 50 after the plurality of MR elements 50 are formed.

In the process of forming the plurality of magnetic field generators 70, first, a photoresist mask 61 is formed on the MR element 50 and the insulating layer 35, as shown in FIG. 16. Next, using the photoresist mask 61 as an etching mask, the insulating layer 35 is etched so that a plurality of groove portions are formed in the insulating layer 35 by ion milling, for example. The plurality of groove portions have a shape corresponding to the plurality of magnetic field generators 70.

Next, as shown in FIG. 17, a plurality of initial magnetic field generators 70P are formed so that the plurality of initial magnetic field generators 70P to later become the magnetic field generators 70 are formed within the plurality of groove portions, leaving the photoresist mask 61 in place. Each of the plurality of initial magnetic field generators 70P at least includes an initial ferromagnetic portion to later become the ferromagnetic portion 73, and the antiferromagnetic portion 72. Next, the photoresist mask 61 is removed.

Next, the magnetization direction of the initial ferromagnetic portion is fixed using laser light and an external magnetic field including a component in a specific direction. The method of fixing the magnetization direction of the initial ferromagnetic portion is the same as the method of fixing the magnetization direction of the initial magnetization pinned layer. That is, each of the plurality of initial magnetic field generators 70P is irradiated with laser light while an external magnetic field is applied thereto. The irradiation of the laser light is performed so that the temperature of the plurality of initial magnetic field generators 70P irradiated with the laser light becomes equal to or higher than a blocking temperature of the antiferromagnetic portion 72. The temperature of the plurality of initial magnetic field generators 70P can be adjusted, for example, by the intensity and pulse width of the laser light. After the irradiation of the laser light, when the temperature of the plurality of initial magnetic field generators 70P becomes lower than the blocking temperature, the magnetization direction of the initial ferromagnetic portion is fixed in the above-described specific direction. This causes the initial ferromagnetic portion to become the ferromagnetic portion 73, and the plurality of initial magnetic field generators 70P to become the plurality of magnetic field generators 70.

For example, in the plurality of initial magnetic field generators 70P to later become the plurality of first magnetic field generators 70A that apply a bias magnetic field to the plurality of first MR elements 50A constituting the resistor sections R11 and R12 of the first detection circuit 10, the magnetization direction of the initial ferromagnetic portion is fixed in the X direction by irradiating the plurality of initial magnetic field generators 70P with laser light while an external magnetic field in the X direction is applied thereto. This causes the initial ferromagnetic portion to become the ferromagnetic portion 73, and the initial magnetic field generator 70P to become the first magnetic field generator 70A. In the plurality of initial magnetic field generators 70P to later become the plurality of first magnetic field generators 70A that apply a bias magnetic field to the plurality of first MR elements 50A constituting the resistor sections R13 and R14 of the first detection circuit 10, the magnetization direction of the initial ferromagnetic portion of each of the plurality of initial magnetic field generators 70P can be fixed in the −X direction by using an external magnetic field in the −X direction. The plurality of first magnetic field generators 70A are thus formed. The plurality of second magnetic field generators 70B are also formed using a method similar to that used to form the plurality of first magnetic field generators 70A.

Note that the intensity of the laser light used to fix the magnetization direction of the initial ferromagnetic portion may be smaller than the intensity of the laser light used to fix the magnetization direction of the initial magnetization pinned layer. The intensity of the laser light used to fix the magnetization direction of the initial ferromagnetic portion may be an intensity such that the change in magnetoresistive change rate, which is the ratio of the magnetoresistive change to the resistance of the MR element 50, is restrained.

Next, an effect of the magnetic sensor 1 according to the example embodiment will be described. In the example embodiment, the second angle θ2 that the second part 70d of the side surface of the magnetic field generator 70 forms with the top surface 70b in the cross section parallel to the XZ plane (second cross section) is greater than the first angle θ1 that the first part 70c of the side surface of the magnetic field generator 70 forms with the top surface 70b in the cross section parallel to the YZ plane (first cross section). According to the example embodiment, this allows the volume of the magnetic field generator 70 to be greater than that when the second angle θ2 is the same as the first angle θ1 or when the second angle θ2 is smaller than the first angle θ1. According to the example embodiment, this allows the strength of the magnetic field generated by the magnetic field generator 70 to be increased.

In the example embodiment, the MR element 50 may be disposed forward of the magnetic field generator 70 in the X or −X direction. If comparison is made at the same position of the top surface 70b of the magnetic field generator 70, according to the example embodiment, it is enabled to cause the bottom surface 70a of the magnetic field generator 70 to be close to the MR element 50 compared to when the second angle θ2 is the same as the first angle θ1 or when the second angle θ2 is smaller than the first angle θ1. According to the example embodiment, this allows the strength of the magnetic field generated by the magnetic field generator 70 and applied to the MR element 50 to be increased.

In the example embodiment, the first angle θ1 may be greater than ½ of the second angle θ2. The first angle θ1 may be great to some extent. If comparison is made using the same size of the bottom surface 70a of the magnetic field generator 70, when the first angle θ1 becomes smaller, the magnitude of the demagnetization field in the cross section parallel to the YZ plane becomes relatively small compared to that of the demagnetization field in the cross section parallel to the XZ plane. In other words, when the first angle θ1 becomes smaller, the magnitude of the demagnetization field in the cross section parallel to the XZ plane becomes relatively large. As a result, it becomes relatively harder to orient the magnetization direction of the ferromagnetic portion 73 of the magnetic field generator 70 in the direction parallel to the X direction.

In contrast, it can be considered to increase the strength of the external magnetic field in the process of fixing the magnetization direction of the initial ferromagnetic portion of the initial magnetic field generator 70P, and to increase the dimension of the magnetic field generators 70 in the direction parallel to the X direction. However, if the strength of the external magnetic field in the process of fixing the magnetization direction of the initial ferromagnetic portion is increased, the magnetization direction of the magnetization pinned layer 52 of the MR element 50 may deviate from a desired direction. If the dimension of the magnetic field generator 70 in the direction parallel to the X direction is increased, the number of MR elements 50 per unit area decreases, and as a result, the MR elements 50 become more susceptible to noise.

In the example embodiment, the above-described problem can be restrained from occurring by increasing the first angle 01 to some extent, to thereby increase the magnitude of the demagnetization field in the cross section parallel to the YZ plane, and cause the magnitude of the demagnetization field in the cross section parallel to the XZ plane to be relatively small.

### Modification Example

Next, first through seventh modification examples of the magnetic sensor 1 according to the example embodiment will be described. Initially, the first modification example will be described with reference to FIG. 18. FIG. 18 is a cross-sectional view showing a part of the first modification example of the magnetic sensor 1. In the first modification example, each of the plurality of first inclined surfaces 33a and the plurality of second inclined surfaces 33b included in the plurality of protruding surfaces 33c is formed in a planar or nearly planar shape. Although not shown in the drawing, the shape of the protruding surface 33c in the cross section parallel to the YZ plane is a triangular shape. The overall shape of each of the plurality of protruding surfaces 33c is a triangular roof shape formed by moving the triangular shape along the direction parallel to the X direction.

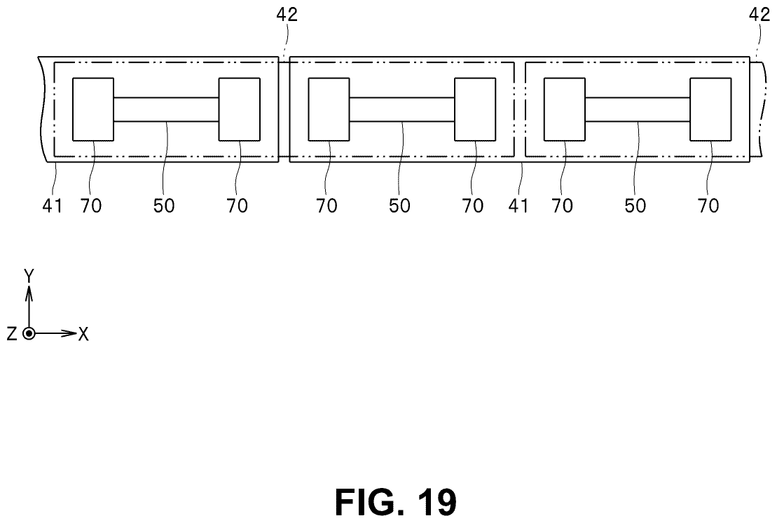

Next, the second modification example will be described with reference to FIG. 19. FIG. 19 is a plan view showing the MR elements 50, the magnetic field generators 70, the lower electrodes 41, and the upper electrodes 42 of the second modification example. In the second modification example, instead of the insulating layer 35, an insulating film formed along the side surface of the MR element 50 is interposed between the MR element 50 and the magnetic field generator 70. When viewed in the Z direction, a part of the magnetic field generator 70 overlaps a part of the MR element 50.

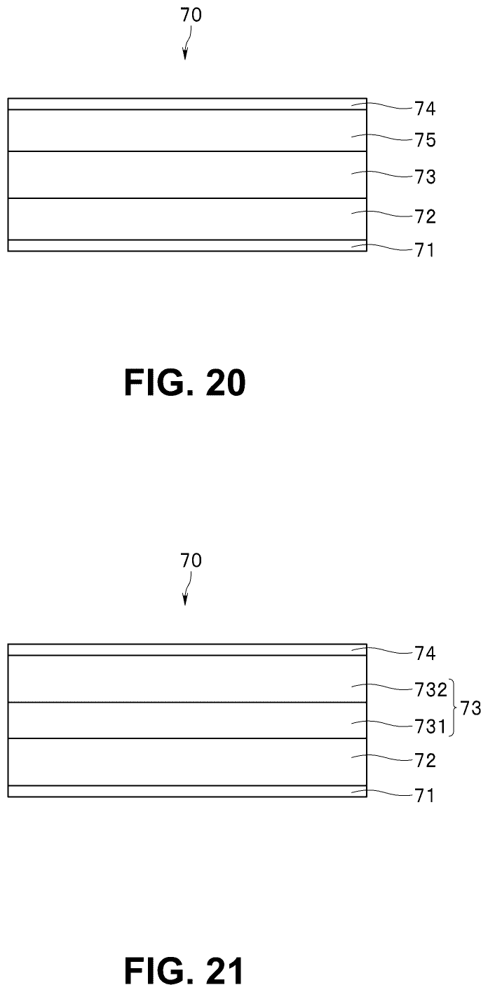

Next, the third modification example will be described with reference to FIG. 20. FIG. 20 is a side view showing the magnetic field generator 70 of the third modification example. In the third modification example, the magnetic field generator 70 further includes an antiferromagnetic portion 75. The antiferromagnetic portion 75 is disposed between the ferromagnetic portion 73 and the cap layer 74. The antiferromagnetic portion 75 is formed of an antiferromagnetic material such as IrMn or PtMn. In the magnetic field generator 70 of the third modification example, the magnetization direction of the ferromagnetic portion 73 is defined by the antiferromagnetic portion 72 and the antiferromagnetic portion 75 in exchange coupling with the ferromagnetic portion 73.

Next, the fourth modification example will be described with reference to FIG. 21. FIG. 21 is a side view showing the magnetic field generator 70 of the fourth modification example. In the fourth modification example, the ferromagnetic portion 73 of the magnetic field generator 70 includes a ferromagnetic layer 731 and a ferromagnetic layer 732. The buffer layer 71, the antiferromagnetic portion 72, the ferromagnetic layer 731, the ferromagnetic layer 732, and the cap layer 74 are stacked in this order. The ferromagnetic layers 731 and 732 are each formed of a ferromagnetic material containing one or more elements selected from the group consisting of Co, Fe, and Ni. In the fourth modification example, the ferromagnetic layer 731 and the ferromagnetic layer 732 each have magnetization in the same direction.

In the fourth modification example, the ferromagnetic layer 731 may be formed of a ferromagnetic material that can increase the exchange coupling energy between the ferromagnetic layer 731 and the antiferromagnetic portion 72, and the ferromagnetic layer 732 may be formed of a ferromagnetic material having a saturation magnetic flux density greater than that of the ferromagnetic material constituting the ferromagnetic layer 731. In such a case, the strength of the bias magnetic field generated by the magnetic field generator 70 can be increased while the exchange coupling energy between the ferromagnetic portion 73 formed of the ferromagnetic layers 731 and 732 and the antiferromagnetic portion 72 is increased, and the magnetic field generator 70 can be made smaller in size. An example of the ferromagnetic layer 731 includes a Co₇₀Fe₃₀ layer. An example of the ferromagnetic layer 732 includes a Co₃₀Fe₇₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

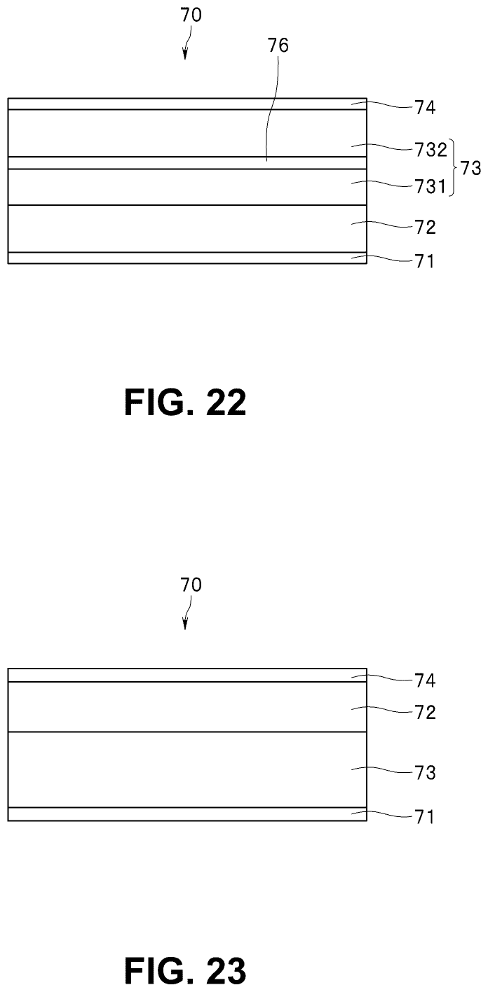

Next, the fifth modification example will be described with reference to FIG. 22. FIG. 22 is a side view showing the magnetic field generator 70 of the fifth modification example. In the fifth modification example, the ferromagnetic portion 73 of the magnetic field generator 70 includes the ferromagnetic layer 731 and the ferromagnetic layer 732. The magnetic field generator 70 further includes a nonmagnetic layer 76. The buffer layer 71, the antiferromagnetic portion 72, the ferromagnetic layer 731, the nonmagnetic layer 76, the ferromagnetic layer 732, and the cap layer 74 are stacked in this order. The ferromagnetic layers 731 and 732 are each formed of a ferromagnetic material containing one or more elements selected from the group consisting of Co, Fe, and Ni. The ferromagnetic layer 731 and the ferromagnetic layer 732 may be formed of the same ferromagnetic material or different ferromagnetic materials. The nonmagnetic layer 76 is formed of a nonmagnetic metallic material such as, for example, Ru.

In the fifth modification example, the ferromagnetic layer 731 and the ferromagnetic layer 732 may be ferromagnetically exchange-coupled with each other via the nonmagnetic layer 76 so as to have the same magnetization direction. In such a case, the ferromagnetic layer 731 and the ferromagnetic layer 732 have magnetization in the same direction. The thickness of the nonmagnetic layer 76 is set to a thickness so as not to lose the exchange coupling between the ferromagnetic layer 731 and the ferromagnetic layer 732. By providing the nonmagnetic layer 76, it is possible to adjust the coercivity of the ferromagnetic portion 73 and to adjust the surface roughness of the base of the ferromagnetic layer 732.

Alternatively, the ferromagnetic layer 731 and the ferromagnetic layer 732 may be antiferromagnetically exchange-coupled with each other via the nonmagnetic layer 76 by the RKKY interaction. In such a case, the magnetization direction of the ferromagnetic layer 731 and the magnetization direction of the ferromagnetic layer 732 are opposite to each other. The magnetization direction of the ferromagnetic portion 73 is the same as the magnetization direction of the ferromagnetic layer 731. When the ferromagnetic layer 731 and the ferromagnetic layer 732 are antiferromagnetically exchange-coupled with each other, the net moment of the ferromagnetic portion 73 becomes small. Therefore, in the ferromagnetic portion 73, the Zeeman energy, which is the energy produced by the external magnetic field acting on the magnetic moment, becomes small. As a result, even when an external magnetic field is applied, the magnetization direction of the ferromagnetic portion 73 is less likely to incline than when the Zeeman energy is large.

The thickness of the nonmagnetic layer 76 is set so that the respective magnetization directions of the ferromagnetic layer 731 and the ferromagnetic layer 732 due to the RKKY interaction become expected directions, and the strength of the exchange coupling by the RKKY interaction becomes an expected strength.

Next, the sixth modification example will be described with reference to FIG. 23. FIG. 23 is a side view showing the magnetic field generator 70 of the sixth modification example. In the sixth modification, the buffer layer 71, the antiferromagnetic portion 72, the ferromagnetic portion 73, and the cap layer 74 of the magnetic field generator 70 are stacked in the order of the buffer layer 71, the ferromagnetic portion 73, the antiferromagnetic portion 72, and the cap layer 74.

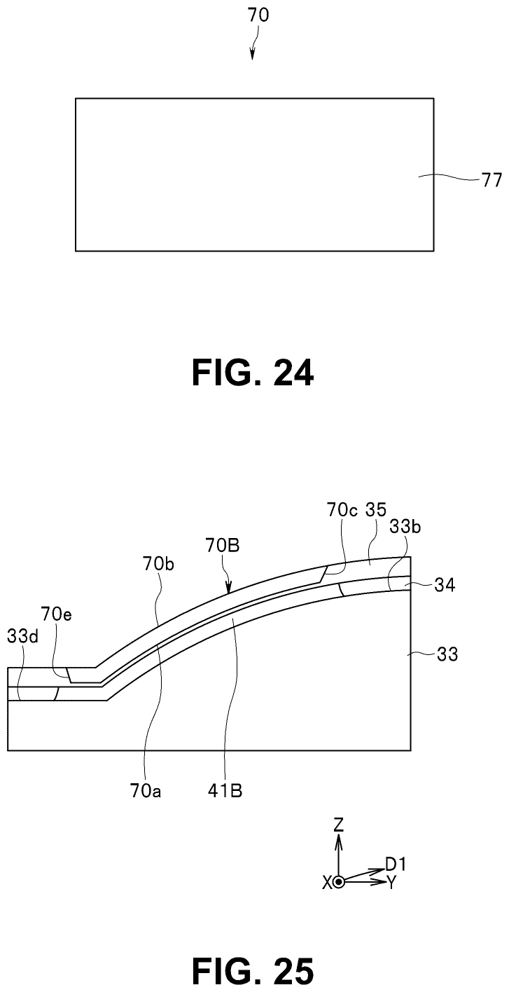

Next, the seventh modification example will be described with reference to FIG. 24. FIG. 24 is a side view showing the magnetic field generator 70 of the seventh modification example. In the seventh modification example, the magnetic field generator 70 includes a magnet 77 formed of a hard magnetic material, instead of the antiferromagnetic portion 72 and the ferromagnetic portion 73. The magnetic field generator 70 may or may not include the buffer layer 71 and the cap layer 74.

### Second Example Embodiment

Next, a second example embodiment of the disclosure will be described with reference to FIG. 25. FIG. 25 is a cross-sectional view showing a part of a magnetic sensor according to the example embodiment. Note that FIG. 25 shows a cross section parallel to the YZ plane and intersecting the second magnetic field generator 70B. Hereinafter, even when descriptions are made with reference to FIG. 25, features common to the first magnetic field generator 70A and the second magnetic field generator 70B will be described as features of the magnetic field generator 70.

In the example embodiment, the third part 70e of the side surface of the magnetic field generator 70 is located above the flat surface 33d of the insulating layer 33. The third angle θ3 that the third part 70e of the side surface of the magnetic field generator 70 forms with the top surface 70b of the magnetic field generator 70 in the cross section parallel to the YZ plane (first cross section) may be the same or nearly the same as the second angle θ2 that the second part 70d of the side surface of the magnetic field generator 70 forms with the top surface 70b of the magnetic field generator 70 in the cross section parallel to the XZ plane (second cross section).

As shown in FIG. 25, a part of the lower electrode 41 may be disposed on the flat surface 33d.

The configuration, operation, and effects of the example embodiment are otherwise the same as those of the first example embodiment.

The disclosure is not limited to each of the foregoing example embodiments, and various modifications may be made thereto. For example, the magnetic sensor 1 of the disclosure may further include a third detection circuit configured to detect a component of the target magnetic field in the direction parallel to the X direction, and to generate at least one third detection signal having a correspondence with this component. In such a case, the processor 2 may be configured to generate, based on the at least one third detection signal, a detection value corresponding to the component of the target magnetic field in the direction parallel to the X direction. The third detection circuit may be integrated with the first and second detection circuits 10 and 20, or may be included in a chip separate from the first and second detection circuits 10 and 20.

As described above, a magnetic sensor according to one embodiment of the disclosure includes a support member including an inclined surface inclined relative to a reference plane, a magnetoresistive element disposed on the inclined surface, and a magnetic field generator that is disposed on the inclined surface and is configured to generate a magnetic field to be applied to the magnetoresistive element. The magnetic field generator includes a bottom surface facing the inclined surface, a top surface opposite the bottom surface, and a side surface connecting the bottom surface and the top surface. The side surface includes a first part located at an end in a first direction, the first direction being along the inclined surface and away from the reference plane, and a second part located at an end in a second direction, the second direction being parallel to the reference plane and along the inclined surface. When a first angle is an angle that the first part forms with the top surface in a first cross section perpendicular to the second direction, and a second angle is an angle that the second part forms with the top surface in a second cross section perpendicular to each of the reference plane and the first cross section, the second angle is greater than the first angle.

In the magnetic sensor according to one embodiment of the disclosure, the first angle may be greater than ½ of the second angle.

In the magnetic sensor according to one embodiment of the disclosure, the side surface may further include a third part located opposite to the first part. When a third angle is an angle that the third part forms with the top surface in the first cross section, the third angle may be greater than the first angle. The first angle may be greater than ½ of the third angle.

In the magnetic sensor according to one embodiment of the disclosure, the magnetoresistive element may be disposed forward of the magnetic field generator in the second direction when viewed in a direction perpendicular to the reference plane.

The magnetic sensor according to one embodiment of the disclosure may further include an insulating layer including a part interposed between the inclined surface and the first part, and a part interposed between the inclined surface and the second part.

In the magnetic sensor according to one embodiment of the disclosure, the magnetic field generator may include a ferromagnetic portion that is formed of a ferromagnetic material, and an antiferromagnetic portion that is formed of antiferromagnetic material and is in exchange coupling with the ferromagnetic portion.

In the magnetic sensor of the disclosure, the second angle that the second part forms with the top surface in the second cross section is greater than the first angle that the first part forms with the top surface in the first cross section. According to the disclosure, this makes it possible to increase the strength of the magnetic field generated by the magnetic field generator disposed on the inclined surface.

Obviously, various modification examples and variations of the disclosure are possible in the light of the above teachings. Thus, it is to be understood that, within the scope of the appended claims and equivalents thereof, the disclosure may be practiced in other embodiments than the foregoing example embodiments.

1. A magnetic sensor comprising:
a support member including an inclined surface inclined relative to a reference plane;
a magnetoresistive element disposed on the inclined surface; and
a magnetic field generator disposed on the inclined surface, the magnetic field generator being configured to generate a magnetic field to be applied to the magnetoresistive element, wherein
the magnetic field generator includes a bottom surface facing the inclined surface, a top surface opposite the bottom surface, and a side surface connecting the bottom surface and the top surface,
the side surface includes a first part and a second part, the first part being located at an end in a first direction, the first direction being along the inclined surface and away from the reference plane, and the second part being located at an end in a second direction, the second direction being parallel to the reference plane and along the inclined surface, and
when a first angle is an angle that the first part forms with the top surface in a first cross section perpendicular to the second direction, and a second angle is an angle that the second part forms with the top surface in a second cross section perpendicular to each of the reference plane and the first cross section, the second angle is greater than the first angle.

2. The magnetic sensor according to claim 1, wherein the first angle is greater than ½ of the second angle.

3. The magnetic sensor according to claim 1, wherein
the side surface further includes a third part located opposite to the first part, and
when a third angle is an angle that the third part forms with the top surface in the first cross section, the third angle is greater than the first angle.

4. The magnetic sensor according to claim 3, wherein the first angle is greater than ½ of the third angle.

5. The magnetic sensor according to claim 1, wherein the magnetoresistive element is disposed forward of the magnetic field generator in the second direction when viewed in a direction perpendicular to the reference plane.

6. The magnetic sensor according to claim 1, further comprising:
an insulating layer including a part interposed between the inclined surface and the first part, and a part interposed between the inclined surface and the second part.

7. The magnetic sensor according to claim 1, wherein the magnetic field generator includes a ferromagnetic portion that is formed of a ferromagnetic material, and an antiferromagnetic portion that is formed of an antiferromagnetic material and is in exchange coupling with the ferromagnetic portion.
